(19) United States
(12) Patent Application Publication
(10) Pub. No.: US 2025/0354259 A1
(43) Pub. Date: Nov. 20, 2025

(54) FILM FORMATION APPARATUS, FILM FORMATION METHOD, AND SUBSTRATE SUPPORT MEMBER

(71) Applicant: Tokyo Electron Limited, Tokyo (JP)

(72) Inventors: Tomoya TOJO, Nirasaki City (JP); Daisuke TORIYA, Nirasaki City (JP); Shinya OKABE, Nirasaki City (JP); Takanobu HOTTA, Nirasaki City (JP)

(21) Appl. No.: 19/204,806

(22) Filed: May 12, 2025

(30) Foreign Application Priority Data
May 15, 2024 (JP) 2024-079656

(51) Int. Cl. C23C 16/44; C23C 16/458

(52) U.S. Cl. CPC C23C 16/4405; C23C 16/4583

(57) ABSTRACT

A film formation apparatus includes an evacuable processing container having a stage therein, a first gas supply portion configured to supply a film formation gas into the processing container to form a film on the substrate, a second gas supply portion configured to supply a cleaning gas that removes a film formed inside the processing container, a through-hole formed in the stage, a substrate support member provided in the through-hole to support the substrate and extending in a vertical direction, a height changing mechanism configured to change a relative height of the stage and the substrate support member to switch between a state in which the substrate is supported by the stage and a state in which the substrate is supported by the substrate support member, and a groove formed on a side surface of the substrate support member and constituting a flow path of the cleaning gas.

### CROSS-REFERENCE TO RELATED APPLICATION

This application is based upon and claims the benefit of priority from Japanese Patent Application No. 2024-079656, filed on May 15, 2024, the entire contents of which are incorporated herein by reference.

### TECHNICAL FIELD

The present disclosure relates to a film formation apparatus, a film formation method, and a substrate support member.

### BACKGROUND

In manufacturing a semiconductor device, various films are formed by supplying gases to a substrate such as a semiconductor wafer (hereinafter referred to as a “wafer”), which is placed on a stage inside a processing container under a vacuum pressure. An apparatus for forming a film may include a substrate support member configured to support and raise/lower the substrate relative to an upper surface of the stage in order to deliver the substrate between a transfer mechanism, which transfers the substrate inside and outside the processing container, and the stage.

Patent Document 1 discloses a lift pin, which serves as the aforementioned substrate support member and has a cutout of a lower side of an enlarged upper end. When evacuating the interior of a processing container, a gas remaining between a substrate and an upper surface of a stage flows through a through-hole, through which the lift pin is inserted on the stage, via the cutout, to be removed, thereby preventing the substrate from slipping on the stage.

### PRIOR ART DOCUMENT

### Patent Document

Patent Document 1: Japanese Patent Laid-open Publication No. 2023-165658

### SUMMARY

According to one embodiment of the present disclosure, a film formation apparatus includes: a processing container having a stage on which a substrate is placed therein and configured to be evacuated; a first gas supply portion configured to supply a film formation gas into the processing container for forming a film on the substrate placed on the stage; a second gas supply portion configured to supply a cleaning gas that removes a film formed inside the processing container by the film formation gas in a state in which the substrate is not accommodated inside the processing container; a through-hole formed in a vertical direction of the stage; a substrate support member provided in the through-hole to support the substrate and extending in the vertical direction; a height changing mechanism configured to change a relative height of the stage and the substrate support member so that the substrate is switched between a state in which the substrate is supported by the stage and a state in which the substrate is supported by the substrate support member; and a groove formed on a side surface of the substrate support member and constituting a flow path of the cleaning gas.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional side view of a film formation apparatus according to an embodiment of the present disclosure.

FIG. 2 is a plan view of a stage in the film formation apparatus.

FIG. 3 is a perspective view of a lift pin provided on the stage.

FIG. 4 is a transversal cross-sectional view of the lift pin.

FIG. 5 is a schematic diagram illustrating a gas flow during a cleaning process in the film formation apparatus.

FIGS. 6A to 6E are process diagrams illustrating an operation of the lift pin in the film formation apparatus.

FIG. 7 is a schematic diagram illustrating a gas flow during a cleaning process in the film formation apparatus.

FIGS. 8A to 8E are process diagrams illustrating an operation of a lift pin in a comparative example.

FIG. 9 is a schematic diagram illustrating a gas flow around the lift pin.

FIG. 10 is a side view illustrating another configuration example of the lift pin.

FIG. 11 is a longitudinal cross-sectional side view of a film formation apparatus including a lift pin of another configuration.

FIG. 12 is a schematic diagram illustrating a result of an evaluation test.

FIG. 13 is a schematic diagram illustrating a result of a comparative test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

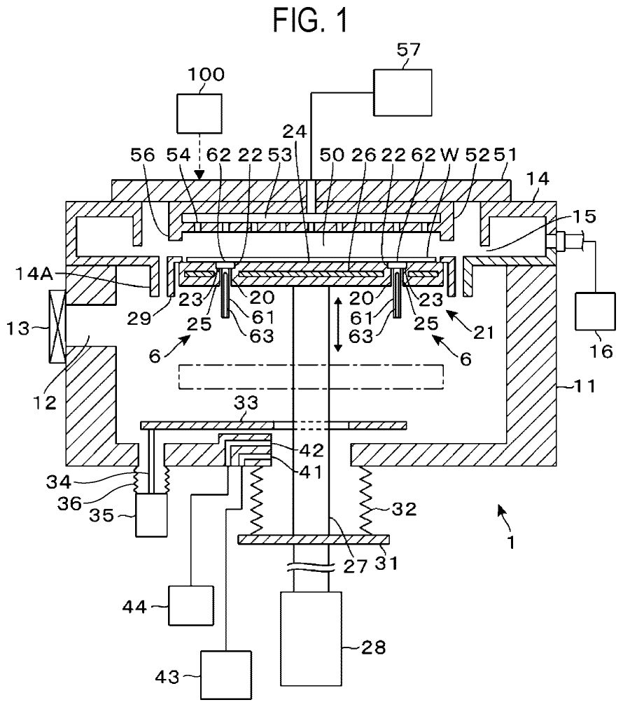

A film formation apparatus 1 according to an embodiment of the present disclosure will now be described with reference to a longitudinal cross-sectional side view of FIG. 1. The film formation apparatus 1 includes a processing container 11, an interior of which is evacuated to a vacuum pressure. A film is formed on a wafer W by accommodating the wafer W inside the processing container 11 and supplying a film formation gas. In this example, a titanium nitride (TiN) film is formed by atomic layer deposition (ALD). After a film formation process is repeated a predetermined number of times on a plurality of wafers W, a cleaning process is performed in which a cleaning gas is supplied into the processing container 11 in a state in which the wafer W is not accommodated inside the processing container 11. As a result, the TiN film formed on each part of the processing container 11 during the film formation process of the wafer W is removed.

The processing container 11 is formed in a circular shape when viewed in a plan view. A sidewall of the processing container 11 is provided with a loading/unloading port 12 of the wafer W and a gate valve 13 for opening and closing the loading/unloading port 12. An exhaust duct 14 is provided above the loading/unloading port 12, is rectangular in a longitudinal cross-sectional view, and is annular in a plan view. The exhaust duct 14 constitutes a part of the processing container 11. An exhaust port 15 is opened on a sidewall of an inner peripheral side of the exhaust duct 14 in a circumferential direction of the exhaust duct 14. Therefore, the exhaust port 15 is formed in the sidewall of the processing container 11, and in a plan view, the exhaust port 15 is annularly formed so as to surround a stage 21 described later.

An exhaust mechanism 16 is connected to the exhaust duct 14. The exhaust mechanism 16 includes a valve installed on an exhaust path or a vacuum pump that evacuates the interior of the processing container 11 through the exhaust path. The amount of exhaust from the exhaust port 15 is regulated by adjusting the opening degree of the valve under control of a controller 100 described later, thereby forming a vacuum atmosphere with a desired pressure inside the processing container 11. In the figure, reference symbol 14A denotes a flow regulation member provided on an inner peripheral side of the exhaust duct, which regulates a gas flow during a film formation process.

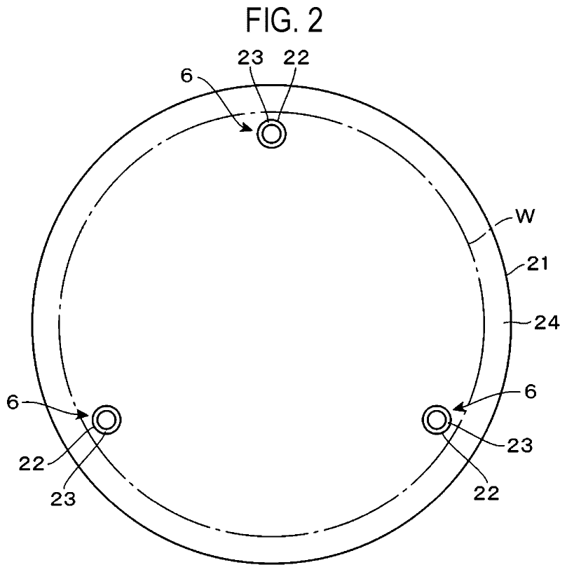

The stage 21 provided inside the processing container 11 will now be described with reference to the plan view of FIG. 2. As illustrated in the figure, the stage 21 is circular in a plan view. A portion of an upper side of the stage 21 is recessed, thereby forming circular recessed portions 22. Three recessed portions 22 are provided at a peripheral portion of the stage 21 and are arranged at intervals in a circumferential direction of the stage 21.

A bottom surface of each recessed portion 22 constitutes a pin support surface 23 that supports a lift pin 6, which will be described later, and is formed as a horizontal surface. An upper surface of the stage 21 outside the recessed portions 22 serves as a wafer support surface 24. The wafer support surface 24 is also formed as a horizontal surface, allowing the wafer W to be horizontally placed on the wafer support surface 24. As described above, each of the pin support surface 23 and the wafer support surface 24 constitutes portions of the upper surface of the stage 21. The wafer support surface 24 occupies most of the upper surface of the stage 21.

As illustrated in FIG. 1, the stage 21 is provided with a through-hole 25 extending in a vertical direction, more specifically, in a longitudinal direction. Upper and lower ends of the through-hole 25 are opened on the pin support surface 23 and a lower surface of the stage 21, respectively. The through-hole 25 is provided for each recessed portion 22. Therefore, while only two through-holes 25 are illustrated in FIG. 1, a total of three through-holes 25 is provided. The through-hole 25 is circular in a plan view. In a plan view, the diameter of the through-hole 25 is smaller than the diameter of the recessed portion 22, and the center of the recessed portion 22 and the center of the through-hole 25 are aligned with each other. Therefore, it can be said that the recessed portion 22 is formed by expanding the diameter of an upper side of the through-hole formed in the stage 21. The lift pin 6 is provided in the through-hole 25, and this lift pin 6 will be described in detail later. A circumferential surface of the through-hole 25 is represented as a hole wall surface 20.

A heater 26 is embedded in the stage 21 to heat the wafer W placed on the aforementioned wafer support surface 24 to a predetermined temperature. A central lower portion of the stage 21 is supported by an upper end of a support 27, and a lower end of the support 27 penetrates a bottom of the processing container 11 and is connected to a lifting mechanism 28 provided outside the processing container 11. The stage 21 is raised and lowered by the lifting mechanism 28 between a standby position at a lower side within the processing container 11, indicated by a dashed line in FIG. 1, and a processing position at an upper side within the processing container 11, indicated by a solid line in FIG. 1.

The standby position is a position at which the wafer W waits to be delivered from a transfer mechanism 10, which enters the processing container 11 through the loading/unloading port 12. The transfer mechanism 10 is not illustrated in FIGS. 1 and 2. The processing position is a position at which the wafer W is processed. In FIG. 1, reference numeral 29 denotes a cover that surrounds a lateral side of the stage 21. When the stage 21 is located at the processing position, the cover 29 faces the flow regulation member 14A and, together with the flow regulation member 14A, the cover 29 suppresses the infiltration of a gas to a lower surface of the stage 21.

In FIG. 1, reference numeral 31 denotes a flange that is attached to the support 27 and located below the bottom of the processing container 11. A bellows 32 that is expandable and contractable is provided surrounding the support 27. The bellows 32 is connected to the bottom of the processing container 11 and the flange 31 so as to ensure airtightness inside the processing container 11.

A support base 33 is provided below the stage 21, and the aforementioned support 27 penetrates this support base 33. The support base 33 is supported by an upper end of a support 34, and a lower end of the support 34 penetrates the bottom of the processing container 11 and is connected to a lifting mechanism 35 provided outside the processing container 11. In a state in which the support base 33 is raised or lowered by the lifting mechanism 35 and three lift pins 6 described later are supported by the support base 33, these lift pins 6 are raised or lowered together. A bellows 36 that is expandable and contractible is provided while surrounding the support 34. The bellows 36 is connected to the bottom of the processing container 11 and the lifting mechanism 35 so as to ensure airtightness inside the processing container 11.

Gas supply ports 41 and 42 are opened at the bottom of the processing container 11. An inert gas supply mechanism 43 and a cleaning gas supply mechanism 44 are connected to the gas supply ports 41 and 42 via gas supply pipes, respectively. The cleaning gas supply mechanism 44 corresponds to a second gas supply portion. An inert gas and a cleaning gas are supplied from the inert gas supply mechanism 43 and the cleaning gas supply mechanism 44 into the processing container 11 via the gas supply ports 41 and 42, respectively.

Specifically, the inert gas is, for example, N₂ gas, and is supplied during the cleaning process in order to adjust the partial pressure of the cleaning gas inside the processing container 11 or during the film formation process in order to prevent the film formation gas from flowing into the lower side of the stage 21. The aforementioned cleaning gas is, for example, ClF₃ gas, and is supplied from the gas supply port 42 in a predetermined stage of the cleaning process as described later. While the respective gases supplied from these gas supply ports 41 and 42 are evacuated through the exhaust port 15 of the aforementioned exhaust duct 14, the gases flow upward inside the processing container 11 and are drawn into the exhaust port 15 and then removed.

A ceiling plate 51 is provided above the exhaust duct 14 so as to cover the processing container 11 from above, and a shower head 52 that is circular in a plan view is provided on a lower surface of the ceiling plate 51. The shower head 52 includes a gas diffusion space 53 provided inside the shower head 52 and a plurality of discharge holes 54 provided on a bottom surface of the shower head 52. Each of the discharge holes 54 is in communication with the gas diffusion space 53 and is formed to face the stage 21. In addition, an annular protrusion 56 that protrudes downward is provided on a peripheral end of the shower head 52 to regulate a gas flow.

When the stage 21 is located at the processing position, the annular protrusion 56 is located close to an upper surface of the cover 29 of the stage 21, so that an area surrounded by the stage 21, the annular protrusion 56, and the shower head 52 constitutes a processing space 50. The discharge holes 54 are opened to this processing space 50, and thus a gas is supplied to the wafer W located in the processing space 50 during the film formation process. When the stage 21 is positioned at the processing position, the exhaust port 15 is positioned laterally from an annular gap formed between the annular protrusion 56 and the cover 29. The gas supplied to the processing space 50 flows laterally to the outside of the processing space 50 and is removed by being drawn into the exhaust port 15.

A gas supply mechanism 57 is connected to the ceiling plate 51. Gases supplied from the gas supply mechanism 57 are supplied to the gas diffusion space 53 through a flow path formed above the ceiling plate 51 and the shower head 52 and are discharged through the discharge holes 54. The gases supplied from the gas supply mechanism 57 are a film-forming gas, an inert gas, and a cleaning gas. The film-forming gas is a gas for forming the TiN film on the wafer W, such as TiCl₄ gas or NH₃ gas. The inert gas is specifically, for example, N₂ gas, and is supplied to purge the processing space 50 during the film formation process by ALD or during the cleaning process to adjust the partial pressure of the cleaning gas inside the processing container 11. The cleaning gas is specifically, for example, ClF₃ gas, which is the same gas as the gas supplied from the gas supply port 42.

The gas supply mechanism 57 corresponds to a first gas supply portion. Each of the gas supply mechanism 57 and the aforementioned gas supply mechanisms 43 and 44 includes a gas supply source in which a gas is stored, a valve installed on a flow path from the gas supply source to the processing container 11, and a flow rate adjustor such as a mass flow controller for adjusting the flow rate of a gas supplied to a downstream side of the flow path.

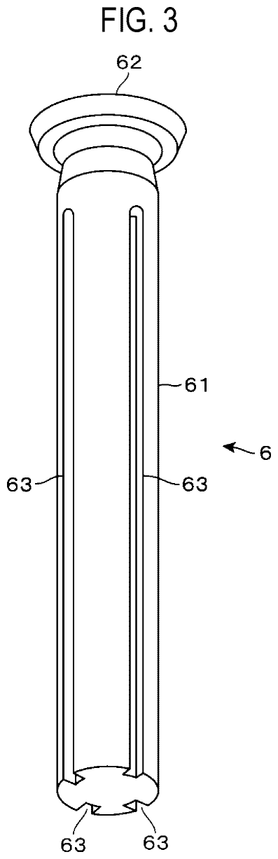

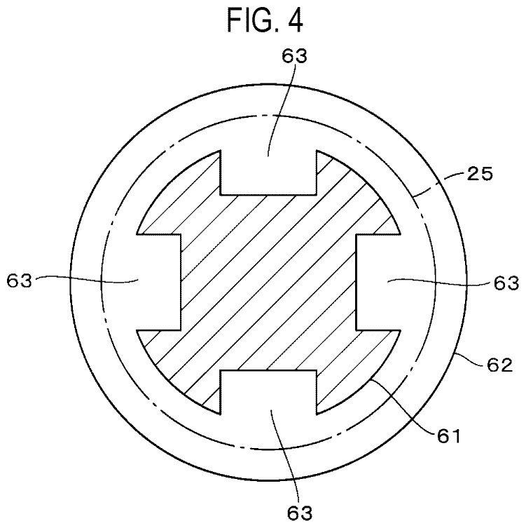

Next, the lift pin 6 provided on the stage 21 will be described with reference to a perspective view of FIG. 3 and a transversal cross-sectional plan view of FIG. 4. The lift pin 6 is a substrate support member that transfers the wafer W between the transfer mechanism 10 and the stage 21 and is provided for each through-hole 25. The lift pin 6 can be raised and lowered relative to the stage 21. In order to suppress thermal expansion, the lift pin 6 is made of, for example, ceramic, more specifically, alumina ceramic.

The lift pin 6 will now be described in more detail. The lift pin 6 is a circular rod-shaped member extending in the vertical direction, more specifically, in the longitudinal direction, and includes a shaft portion 61 and a head portion 62 provided above the shaft portion 61. The shaft portion 61 and the head portion 62 are each circular when viewed in an extension direction (i.e., longitudinal direction) of the lift pin 6, and respective central axes thereof are aligned with each other. As will be described later, a diameter of the head portion 62 is larger than a diameter of the shaft portion 61 when viewed in the extension direction of the lift pin 6 so that the head portion 62 blocks the through-hole 25 during the film formation process. Therefore, a cross-sectional area of the head portion 62 is larger than a cross-sectional area of the shaft portion 61 when viewed in the extension direction.

The diameter of the shaft portion 61 is slightly smaller than the diameter of the through-hole 25 of the stage 21, and the shaft portion 61 is inserted through the through-hole 25 of the stage 21. The diameter of the head portion 62 is slightly smaller than the diameter of the recessed portion 22 of the stage 21. When the stage 21 is at the processing position, a lower end of the lift pin 6 (a lower end of the shaft portion 61) is separated from the support base 33, and the head portion 62 is inserted into the recessed portion 22 and supported by the pin support surface 23 of the recessed portion 22, thereby blocking the through-hole 25 from above.

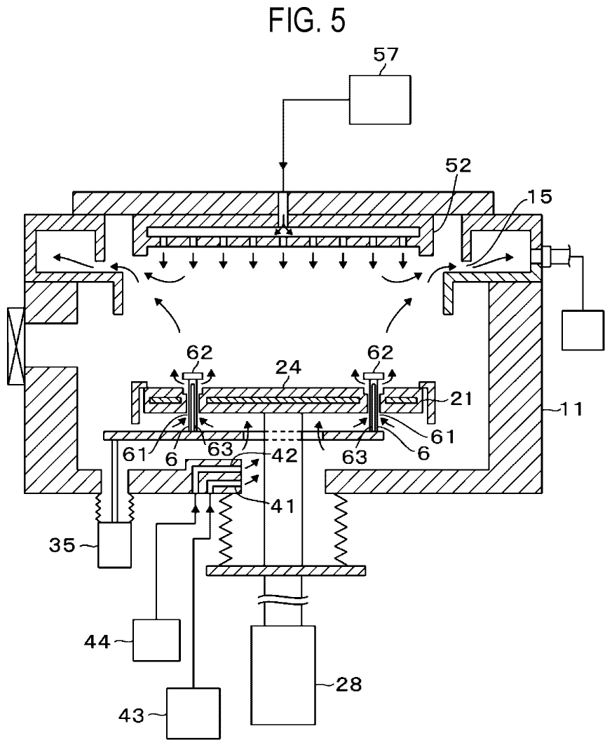

When the stage 21 is at the standby position, as illustrated in FIG. 5, the lower end of the lift pin 6 contacts the support base 33, and the head portion 62 of the lift pin 6 extends out from the recessed portion 22 and is positioned above the wafer support surface 24. Since the lift pin 6 contacts the support base 33 in this way, the lift pin 6 is raised or lowered together with the raising and lowering of the support base 33 by the lifting mechanism 35, thereby changing the height position of the lift pin 6 relative to the stage 21. In addition, when the lift pin 6 is supported by the support base 33 in this manner, the height position of the lift pin 6 relative to the stage 21 also changes even when the stage 21 is raised or lowered by the lifting mechanism 28. Therefore, the lifting mechanisms 28 and 35 function as height changing mechanisms that change the relative height between the stage 21 and the lift pin 6, and this change in the relative height switches between a state in which the wafer W is supported on the wafer support surface 24 and a state in which the wafer W is supported by the lift pin 6 floating above the wafer support surface 24. FIG. 5 illustrates a position of the lift pin 6 when the cleaning gas is supplied from the gas supply port 42 and the cleaning process is performed, and this cleaning process will be described in detail later.

The shaft portion 61 is provided with grooves 63 that extend from an upper end thereof to a lower end thereof in an extension direction of the shaft portion 61. Four grooves 63 are provided and are separated from each other when viewed in the extension direction. The grooves 63 are formed at equal intervals in a circumferential direction of the shaft portion 61. In this example, as illustrated in FIG. 4, side surfaces and bottom surfaces of the grooves 63 are formed to be perpendicular to each other. As described above, since the shaft portion 61 is provided inside the through-hole 25, the grooves 63 are positioned to face the hole wall surface 20 of the through-hole 25. As will be described in detail later, each of the grooves 63 forms a flow path of the cleaning gas when the cleaning gas is supplied from the gas supply port 42 to perform cleaning.

Referring back to FIG. 1, the film formation apparatus 1 includes the controller 100, which is a computer. The controller 100 includes programs. The programs incorporate commands (steps) for executing delivery of the wafer W from the transfer mechanism 10, the film formation process on the wafer W, and the cleaning process. The programs are stored in a non-transitory computer readable storage medium, for example, a compact disc, a hard disk, or a DVD and are installed in the controller 100. The controller 100 outputs a control signal to each part of the film formation apparatus 1 according to the programs and controls the operation of each part. Specifically, the controller 100 controls the opening and closing of the gate valve 13, the raising and lowering of the stage 21 and the support base 33 by the lifting mechanisms 28 and 35, the supply of gases from the gas supply mechanisms 43, 44, and 57 into the processing container 11, the temperature of the heater 26, and the operation of the exhaust mechanism 16.

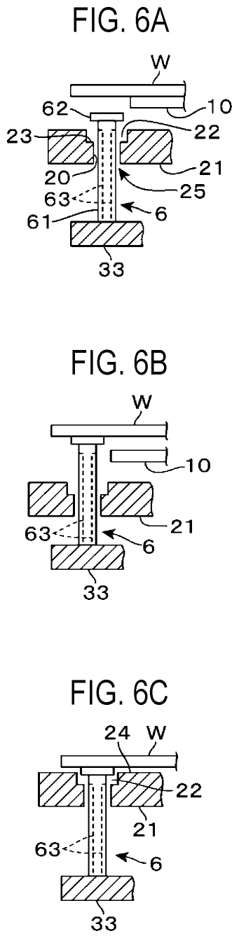

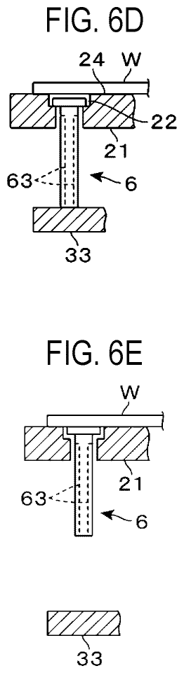

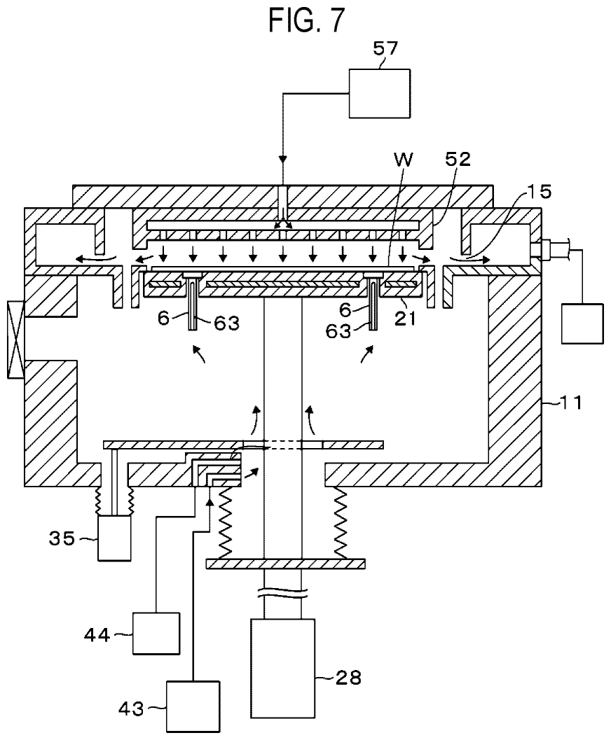

Next, the loading of the wafer W into the film formation apparatus 1 and the film formation process on the wafer W will be described with reference to the process diagram of FIGS. 6A to 6E illustrating operations of the stage 21 and the lift pin 6 and the schematic diagram of FIG. 7 illustrating the film formation apparatus 1. In FIG. 7, a gas flow formed in the processing container 11 is indicated by arrows.

First, in a state in which the stage 21 is positioned at the standby position and an upper side of the lift pin 6 including the head portion 62 protrudes upward from the recessed portion 22 of the stage 21, the transfer mechanism 10 supporting the wafer W enters the processing container 11 through the loading/unloading port 12 and is positioned above the stage 21 (FIG. 6A). The support base 33 rises to push up the lift pin 6, so that the lift pin 6, instead of the transfer mechanism 10, supports the wafer W (FIG. 6B). The transfer mechanism 10 retreats to the outside of the processing container 11, the loading/unloading port 12 is closed, and the stage 21 rises. As the stage 21 rises, the head portion 62 of the lift pin 6 approaches the stage 21. Then, the stage 21 stops temporarily at a position at which the wafer support surface 24 is close to the wafer W (a preheating position), and the wafer W is heated by radiant heat from the stage 21 (FIG. 6C).

Thereafter, the stage 21 resumes rising. As a result, the wafer W is placed on the wafer support surface 24, and the temperature rises further while the head portion 62 of the lift pin 6 is retracted into the recessed portion 22 of the stage 21 (FIG. 6D). The stage 21 then rises further, and the pin support surface 23 of the recessed portion 22 supports the lift pin 6 instead of the support base 33, and the lift pin 6 is separated from the support base 33. Thereafter, when the stage 21 reaches the processing position, the stage 21 stops rising (FIG. 6E).

Then, TiCl₄ gas, a purge gas (inert gas), NH₃ gas, and the purge gas are supplied to the processing space 50 in this order, and this series of gas supplies is repeated as one cycle to form the TiN film on the wafer W. Arrows in FIG. 7 indicate a gas flow during the film formation process. When the above cycle is repeated a predetermined number of times and the film formation process is completed, a reverse operation of loading the wafer W into the processing container 11 described with reference to FIGS. 6A to 6E is performed, and thus the wafer W on which the film has been formed is unloaded from the processing container 11. Such loading of the wafer W into the processing container 11, the film formation process, and unloading of the wafer W from the processing container 11 are repeated. As described above, when the film formation process is performed on a predetermined number of wafers W, the cleaning process is performed.

During the film formation process, however, the through-hole 25 is blocked by the head portion 62 of the lift pin 6 as described above. However, a small amount of film formation gases (TiCl₄ gas and NH₃ gas) may enter the through-hole 25 through a small-sized gap between the head portion 62 and the pin support surface 23 of the recessed portion 22, which may result in film formation on the side surface of the shaft portion 61 of the lift pin 6. A film 60 formed on the shaft portion 61 grows as the film formation process on the wafer W is repeated. The lift pin 6 of the film formation apparatus 1 is configured to ensure a reliable removal of the film 60 during the cleaning process, thereby preventing any issues caused by the remaining film 60.

In describing in detail the cleaning process and advantages of the configuration of the lift pin 6 during the cleaning process, the operation of a film formation apparatus 1A of a comparative example will now be described. This film formation apparatus 1A has the same configuration as the film formation apparatus 1, except that a lift pin 6A is provided instead of the lift pin 6. The lift pin 6A has the same configuration as the lift pin 6, except that the groove 63 is not provided.

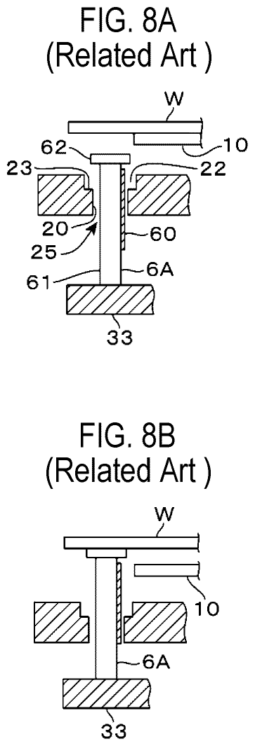

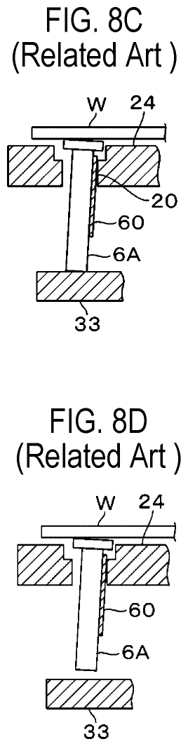

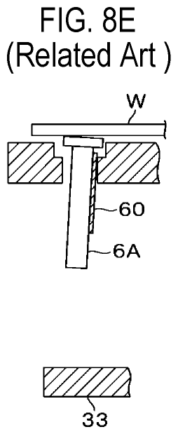

Since a gap between the shaft portion 61 of the lift pin 6A and the hole wall surface 20 of the through-hole 25 is relatively small, it is difficult for the cleaning gas to flow therethrough. Therefore, there is a concern that, even after the cleaning process is performed, the film 60 may not be completely removed and may remain after the cleaning process. Then, the film formation process is repeated after the cleaning process, so that the film 60 grows. FIGS. 8A to 8E illustrate states of the lift pin 6A that are likely to occur, when the wafer W is delivered from the transfer mechanism 10 to the stage 21 and then the stage 21 is moved to the processing position in a state in which the film 60 has grown.

As described with reference to FIGS. 6A to 6E, after the wafer W is transferred from the transfer mechanism 10 to the lift pins 6A (FIGS. 8A and 8B), the stage 21 rises from the standby position and stops at a preheating position at which the wafer support surface 24 is close to the wafer W (FIG. 8C). For example, when the stage 21 rises, the side surface of the shaft portion 61 comes into contact with the hole wall surface 20. As the film 60 is formed, friction between the side surface of the shaft portion 61 and the hole wall surface 20 increases, so that the shaft portion 61 is supported by the hole wall surface 20. In other words, the lift pin 6A is caught on the hole wall surface 20, thereby preventing the lift pin 6A from descending relative to the stage 21.

Thereafter, as the stage 21 rises from the preheating position toward the processing position, the lift pin 6A continues to be caught. As a result, even if the support base 33 is separated from the lift pin 6A, the head portion 62 of the lift pin 6A is not retracted into the recessed portion 22 and continues to protrude above the wafer support surface 24 (FIG. 8D). Therefore, the support of the wafer W by the head portion 62 continues, so that a portion of the wafer W supported by the head portion 62 and a portion therearound are not placed on the wafer support surface 24 and continue to be lifted from the wafer support surface 24.

In addition, in a state where these portions are not sufficiently heated, the stage 21 reaches the processing position and then the film formation process starts (FIG. 8E). Therefore, the process is performed in a state in which the temperature uniformity in the plane of the wafer W is low, and as a result, the film thickness of the TiN film formed on the wafer W has a relatively large variation in the plane of the wafer W. Although the lift pin 6A has been described as being caught when the stage 21 moves from the standby position to the preheating position, this is exemplary and other cases in which the lift pin 6A is caught may occur at various timings of the other operations.

As a way to address these issues, the shaft portion 61 of the lift pin 6A and the hole wall surface 20 of the through-hole 25 can be configured to have a relatively large gap therebetween. This increases the flowability of the cleaning gas through the gap, thereby preventing the film 60 from remaining during the cleaning process. Specifically, increasing the diameter of the through-hole 25 relative to the diameter of the shaft portion 61 can enhance the flowability of the cleaning gas.

However, if the diameter of the through-hole 25 is large compared to the diameter of the shaft portion 61, the shaft portion 61 may tilt relatively significantly within the through-hole 25. This may cause problems. Specifically, for example, the tilted shaft portion 61 may ride on and be supported by the pin support surface 23 of the recessed portion 22 or the wafer support surface 24, so that the lift pin 6 may not perform a lifting operation with respect to the stage 21 as described with reference to FIGS. 6A to 6E. In addition, if the gap between the shaft portion 61 and the hole wall surface 20 of the through-hole 25 becomes excessively large, a portion in the plane of the wafer W overlapping with the gap is not sufficiently heated. This results in deterioration in the uniformity of the temperature distribution in the plane of the wafer W. As a result, there is also a concern that the film thickness uniformity of the TiN film formed on the wafer W will also deteriorate.

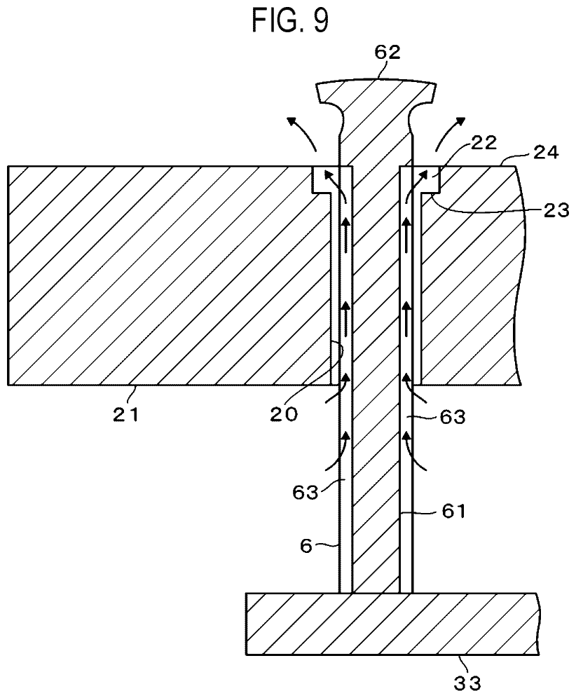

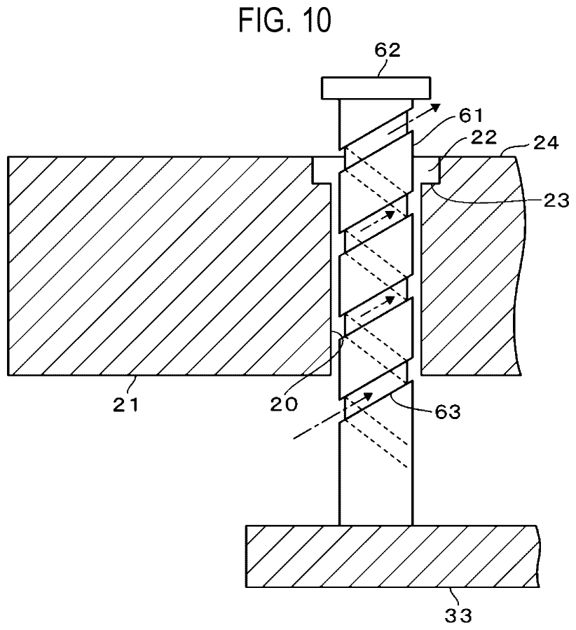

Therefore, in the film formation apparatus 1, the groove 63 constituting a flow path of the cleaning gas is formed in the shaft portion 61 so as to remove the film 60 of the shaft portion 61 reliably by increasing the flowability of the cleaning gas between the shaft portion 61 and the hole wall surface 20 of the through-hole 25. Hereinafter, a cleaning process in the film formation apparatus 1 will be described with reference to FIG. 9 and FIG. 5 described above. FIG. 5 is a schematic diagram illustrating a gas flow inside the processing container 11 using arrows, and FIG. 9 illustrates in detail a gas flow around the lift pin 6 illustrated in FIG. 5.

The stage 21 is positioned at the standby position, and the lift pin 6 is supported on the support base 33. In this case, an upper end of the groove 63 in the shaft portion 61 is positioned above the pin support surface 23 of the recessed portion 22 constituting an upper surface of the stage 21. Since the groove 63 is formed to extend to a lower end of the shaft portion 61, the lower end of the groove 63 is positioned below a lower surface of the stage 21. That is, the lift pin 6 is arranged in such a state that the groove 63 extends from a height position above the through-hole 25 to a height position below the through-hole 25. Then, the inert gas is supplied from the shower head 52, and the inert gas and the cleaning gas are supplied from the gas supply ports 41 and 42, respectively, and as illustrated in FIG. 5, these gases flow toward the exhaust port 15.

In this way, when the gas flow is formed as illustrated in FIG. 9, a portion of the cleaning gas supplied into the processing container 11 enters the groove 63 from a lower side of the stage 21 and flows upward through the gap formed between the groove 63 and the hole wall surface 20. Then, the cleaning gas flows out through this gap onto the pin support surface 23 and moves toward the exhaust port 15.

In the side surface of the shaft portion 61 of the lift pin 6, a relatively large gap is formed between a portion in which the groove 63 is formed and the hole wall surface 20. As described above, the groove 63 is formed extending from above the pin support surface 23 constituting the upper surface of the stage 21 to the lower surface of the stage 21, thereby forming an enlarged gas inlet and an enlarged gas outlet. Accordingly, the cleaning gas flows into the gap formed by the groove 63, flows through the gap, and flows out of the gap at a relatively high flow velocity.

Further, in the side surface of the shaft portion 61, the gap formed between an outer portion of the groove 63 and the hole wall surface 20 of the through-hole 25 is relatively small. However, since the cleaning gas flows at a relatively high flow velocity through the gap formed between the groove 63 and the hole wall surface 20 as described above, the flow velocity of the cleaning gas also increases in a gap formed by an outer portion of the groove 63 which is connected to the gap formed by the groove 63. Therefore, the cleaning gas flows at a high flow velocity through each portion around the shaft portion 61 of the lift pin 6 compared to each portion around the shaft portion 61 of the lift pin 6A, thereby removing the film 60 formed on each portion of the side surface of the shaft portion 61.

The TiN film attached to each portion of the processing container 11, other than the shaft portion 61, is also removed by exposure to the cleaning gas. The cleaning process includes a process of performing cleaning by positioning the stage 21 in a standby state (referred to as a lower-side cleaning process) and an upper-side cleaning process, as illustrated in FIGS. 5 and 9. The upper-side cleaning process is performed in a state in which the stage 21 is positioned at the processing position illustrated in FIG. 7, and along with the cleaning gas and the inert gas being supplied from the shower head 52, the cleaning gas is supplied from the gas supply port 42. The supplied gases flow into the exhaust port 15 and are evacuated in the same manner as when the lower-side cleaning process is performed.

In the upper-side cleaning process, since the upper side of the through-hole 25 is blocked by the head portion 62 of the lift pin 6, it is difficult for the cleaning gas to flow into the gap between the shaft portion 61 and the hole wall surface 20 compared to the lower-side cleaning process. Therefore, removing the film 60 on the shaft portion 61 of the lift pin is mainly performed in the lower-side cleaning process. Either the lower-side cleaning process or the upper-side cleaning process may be performed first. After the cleaning process is completed, the loading of the wafer W into the processing container 11, the film formation on the wafer W, and the unloading of the wafer W from the processing container 11, described with reference to FIGS. 6A to 6E and 7, are resumed.

As described above, according to the film formation apparatus 1, even if the film 60 is formed on the side surface of the shaft portion 61 of the lift pin 6, the film 60 is removed reliably by increasing flowability of the cleaning gas around the shaft portion 61 by the groove 63 formed in the shaft portion 61 during the cleaning process. Therefore, it is possible to suppress a variation in the film thickness in the plane of the wafer W due to the abnormal placement of the wafer W on the stage 21 described with reference to FIGS. 8A to 8E. As a result, a decrease in the yield of semiconductor products manufactured from the wafer W can be suppressed.

In addition, the shaft portion 61 of the lift pin 6 is structured such that only a part of a circumferential surface of the shaft portion 61 is recessed toward the center of the shaft portion 61 as the groove 63, compared to the shaft portion 61 of the lift pin 6A. Therefore, the tilting of the lift pin 6 caused by the enlargement of the through-hole 25 relative to the shaft portion 61 described above is prevented. Further, since the gap between the shaft portion 61 and the hole wall surface 20 of the through-hole 25 is prevented from becoming excessively large, a decrease in the temperature uniformity of the wafer W is also suppressed.

The film 60 has been described as being formed and grown on the shaft portion 61. However, even in a case where the TiN film is formed and grown, for example, on the hole wall surface 20, there is a concern that placement abnormality of the wafer W as shown in FIG. 8A to 8E may occur. However, even in the case in which the film 60 is formed on the hole wall surface 20 as described above, since the flowability of the cleaning gas in the gap around the shaft portion 61 is increased as described with reference to FIGS. 5 and 9, the film 60 is removed reliably, thereby preventing the occurrence of such placement abnormality.

The shape of the groove 63 formed in the shaft portion 61 is not limited to a shape in which the side surface of the groove 63 and the bottom surface of the groove 63 are perpendicular to each other. For example, the groove 63 may be formed so that the width thereof narrows in a depth direction thereof, thereby forming a fan shape in a transversal cross-sectional view. The number of grooves 63 is not limited to four and any number can be provided. In addition, one groove may branch into multiple grooves as the groove extends, or multiple grooves may merge as the grooves extend.

The groove 63 is not limited to being formed in an extension direction of the shaft portion 61. For example, as illustrated in a side view of FIG. 10, the groove 63 may be formed in a spiral shape on the side surface of the shaft portion 61. In FIG. 10, the lift pin 6 when the lower-side cleaning process is performed is illustrated similarly to FIG. 9, and the gas flow is indicated by a dashed arrow. In addition, the shape of the lift pin 6 and the shape of the through-hole 25 are not limited to the examples described earlier and may be changed as appropriate. For example, each of the lift pin 6 and the through-hole 25 may have a rectangular shape in transversal cross-section.

In addition, the film 60 has been described as being removed by supplying the cleaning gas from the gas supply port 42 provided below the stage 21 using a positional relationship in which an upper end of the groove 63 is positioned above the pin support surface 23 of the recessed portion 22 as illustrated in FIG. 9. In this positional relationship between the stage 21 and the lift pin 6, the film 60 may be removed by supplying the cleaning gas from the shower head 52 instead of supplying the cleaning gas from the gas supply port 42. In other words, when removing the film 60, the cleaning gas may be supplied to the groove 63 from the upper side or the lower side of the stage 21. However, in the film formation apparatus 1, when the stage 21 and the lift pin 6 are positioned as illustrated in FIG. 9, since the exhaust port 15 is positioned on the upper side of the stage 21, it is desirable to supply the cleaning gas from the gas supply port 42 below the lower side of the stage 21 as described above in order to supply a sufficient amount of cleaning gas into the groove 63.

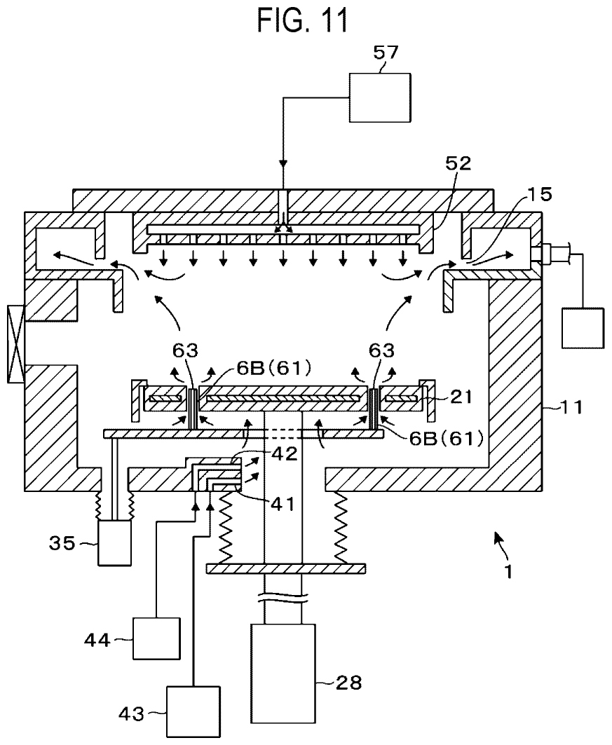

FIG. 11 illustrates a longitudinal cross-sectional side view of the film formation apparatus 1 provided with a lift pin 6B which is another configuration example of the lift pin. A lower end of the lift pin 6B is fixed to the support base 33 and the lift pin 6B rises and falls together with the support base 33. The lift pin 6B does not have the head portion 62, and the groove 63 is formed extending from the upper end to the lower end of the shaft portion 61. Therefore, the entirety of the lift pin 6B constitutes the shaft portion 61, and the groove 63 is formed extending from the upper end to the lower end of the lift pin 6B. In accordance with the shape of the lift pin 6B, the stage 21 is not provided with the recessed portion 22, and the through-hole 25 is formed extending from the upper surface to the lower surface of the stage 21. By raising and lowering the support base 33 relative to the stage 21 at the standby position, an upper end of the lift pin 6B protrudes from and retracts into the wafer support surface 24 of the stage 21, thereby delivering the wafer W between the stage 21 and the transfer mechanism 10. Then, in the lower-side cleaning process, as illustrated in FIG. 11, the cleaning gas passes through the groove 63, and thus the film 60 on the side surface of the lift pin 6B is removed in the same manner as the lift pin 6.

As described with the lift pin 6B, the lift pin may be fixed to the support base 33 without being provided with the head portion 62 or may be provided with the groove 63 to remove the film 60 reliably. Further, since the lift pin 6B is fixed to the support base 33 as described above, the abnormal placement of the wafer W as described with reference to FIGS. 8A to 8E in which the lift pin 6B continues to be supported by the stage 21 due to the film 60 does not occur. Furthermore, when the stage 21 is positioned at the processing position, the lift pin 6B is positioned outside the through-hole 25. Accordingly, the lift pin 6B outside the through-hole 25 can be exposed to the cleaning gas supplied from the gas supply port 42 in the upper-side cleaning process. Therefore, it is particularly effective for the groove 63 to be formed on the shaft portion 61 of the lift pin that has the head portion 62 and the shaft portion 61 and is configured such that the shaft portion 61 is always positioned within the through-hole 25, like the lift pin 6.

The shape of the lift pin may be appropriately modified from each of the examples described above and may be, for example, a square-bar shape. The configuration of the film formation apparatus is not limited to the film formation apparatus 1 described above and may be an apparatus that forms a film of a type other than the TiN film. The film formation apparatus may be an apparatus that forms a film by chemical vapor deposition (CVD) without being limited to the apparatus that forms a film by atomic layer deposition (ALD). The film formation apparatus 1 forms a film on the wafer W in an environment in which no plasma is formed but an apparatus configured to form a film in a plasma environment may be possible.

In the film formation apparatus 1, the exhaust port 15 is provided on the sidewall of the processing container 11 so as to surround the stage 21 and perform exhaust from the lateral side of the stage 21 toward the outer periphery of the stage 21 during the film formation process. The film formation apparatus 1 is not limited to an apparatus provided with the exhaust port 15 in this manner and may be configured, for example, such that the exhaust port 15 is opened at the bottom of the processing container 11 and performs exhaust downward from the stage 21 during the film formation process.

However, in the case of the film formation apparatus 1 in which the exhaust port 15 is provided on the sidewall of the stage 21 and performs exhaust toward the outer periphery of the stage 21, an exhaust flow generated by the exhaust port 15 has difficulty passing through the through-hole 25. Therefore, if a film formation gas leaks into the through-hole 25 as described above, the film formation gas will remain in the through-hole 25 and it is considered that the film 60 is easily formed. In other words, this technology is particularly effective when applied to a film formation apparatus in which the exhaust port 15 is provided on the sidewall of the stage 21.

It should be noted that the embodiments disclosed herein are exemplary in all aspects and are not restrictive. The above-described embodiments may be omitted, replaced, or modified in various forms without departing from the scope and spirit of the appended claims.

### <Evaluation Test>

An evaluation test related to this technology will be described. As evaluation test 1, a simulation was performed to measure a distribution of a gas flow velocity inside the processing container 11 of the film formation apparatus 1 during the lower-side cleaning process. In this simulation, N₂ gas, instead of the cleaning gas, was set to be supplied from the gas supply port 42. In comparative test 1, a simulation was performed with the same settings as in evaluation test 1, except that the lift pin 6A described above was provided instead of the lift pin 6.

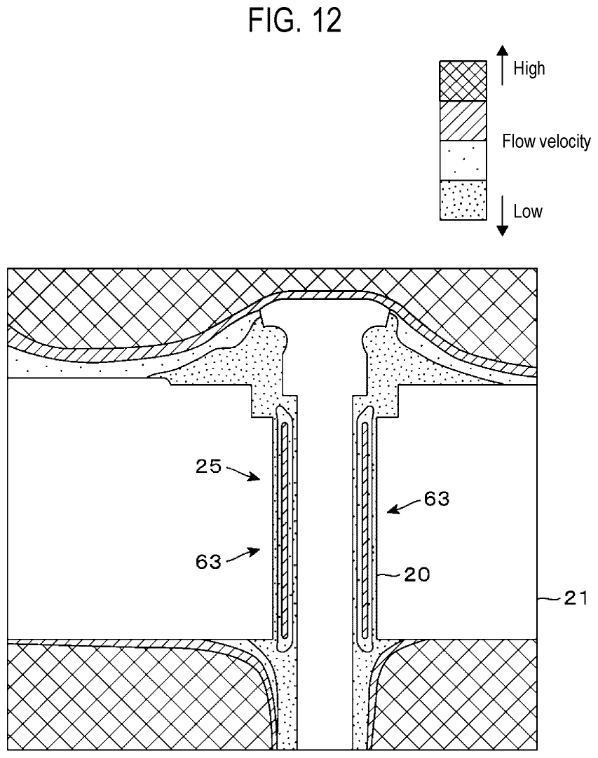

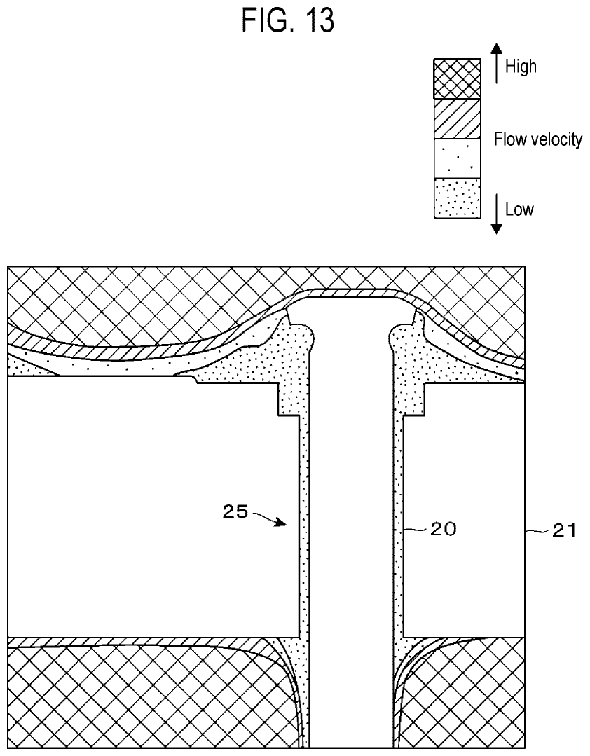

FIGS. 12 and 13 illustrate test results of evaluation test 1 and comparative test 1, respectively, and are schematic diagrams illustrating gas flow velocity distributions around the lift pins 6 and 6A. Actual test results were obtained as gradient images in which the flow velocity of each portion corresponds to a related color through computer graphics. However, in FIGS. 12 and 13, the distribution of flow velocity is illustrated by enclosing areas in which the flow velocity is similar with contour lines and assigning a shape within the enclosed areas according to a flow velocity range.

As illustrated in FIG. 13, in comparative test 1, a gas flow velocity in the gap between the shaft portion 61 of the lift pin 6A and the hole wall surface 20 of the through-hole 25 was relatively low. However, as illustrated in FIG. 12, in evaluation test 1, a gas flow velocity in the gap between the groove 63 of the shaft portion 61 and the hole wall surface 20 was higher than the gas flow velocity in comparative test 1. More specifically, in comparative test 1, the flow velocity in some parts in the above gap was 0.003 m/sec, and in evaluation test 1, the flow velocity in some parts in the above gap was 0.015 m/sec. It is obvious that the cleaning gas also exhibits behavior similar to that of N₂ gas. Accordingly, it can be said that evaluation test 1 and comparative test 1 showed that the flowability of the cleaning gas in the gap between the shaft portion 61 and the hole wall surface 20 can be improved by providing the groove 63. Therefore, from these tests, it is presumed that the abnormality in the placement state of the wafer W can be prevented as described in the embodiment.

According to the present disclosure in some embodiments, it is possible to prevent problems that can arise in processing a subsequent substrate due to a film residue after a previous process.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film formation apparatus, comprising:
a processing container having a stage on which a substrate is placed therein and configured to be evacuated;
a first gas supply portion configured to supply a film formation gas into the processing container for forming a film on the substrate placed on the stage;
a second gas supply portion configured to supply a cleaning gas that removes a film formed inside the processing container by the film formation gas in a state in which the substrate is not accommodated inside the processing container;
a through-hole formed in a vertical direction of the stage;
a substrate support member provided in the through-hole to support the substrate and extending in the vertical direction;
a height changing mechanism configured to change a relative height of the stage and the substrate support member so that the substrate is switched between a state in which the substrate is supported by the stage and a state in which the substrate is supported by the substrate support member; and
a groove formed on a side surface of the substrate support member and constituting a flow path of the cleaning gas.

2. The film formation apparatus of claim 1, wherein the substrate support member includes a shaft portion and a head portion, which has a larger cross-sectional area than the shaft portion when viewed in an extension direction of the substrate support member and is provided above the shaft portion,
wherein the stage is provided with a recessed portion into which the head portion is retracted, a bottom surface of the recessed portion constituting a part of an upper surface of the stage, and
wherein the groove is provided on the shaft portion.

3. The film formation apparatus of claim 2, wherein, when the cleaning gas is supplied into the processing container, an upper end of the groove is located above the upper surface of the stage and a lower end of the groove is located below a lower surface of the stage.

4. The film formation apparatus of claim 2, wherein the groove is provided in multiple numbers so that the grooves are spaced apart from each other when viewed in the extension direction of the substrate support member.

5. The film formation apparatus of claim 1, wherein an exhaust port is provided on a sidewall of the processing container for performing exhaust toward an outer periphery of the stage.

6. A film forming method, comprising:
placing a substrate on a stage provided inside a processing container and having a through-hole formed in a vertical direction;
evacuating an interior of the processing container;
forming a film on the substrate placed on the stage by supplying a film formation gas from a first gas supply portion into the processing container;
removing a film formed inside the processing container by the film formation gas by supplying a cleaning gas from a second gas supply portion into the processing container in a state in which the substrate is not accommodated in the processing container;
changing a relative height of the stage and a substrate support member using a height changing mechanism so that the substrate is switched between a state in which the substrate is supported by the stage and a state in which the substrate is supported by the substrate support member; and
allowing the cleaning gas to flow through a groove which is formed on a side surface of the substrate support member and constitutes a flow path of the cleaning gas.

7. A substrate support member for use in a film formation apparatus, which includes: a processing container having a stage on which a substrate is placed therein and configured to be evacuated; a first gas supply portion configured to supply a film formation gas into the processing container for forming a film on the substrate placed on the stage; a second gas supply portion configured to supply a cleaning gas that removes a film formed inside the processing container by the film formation gas in a state in which the substrate is not accommodated inside the processing container; a through-hole formed in a vertical direction in the stage; the substrate support member provided in the through-hole to support the substrate and extending in the vertical direction; and a height changing mechanism configured to change a relative height of the stage and the substrate support member so that the substrate is switched between a state in which the substrate is supported by the stage and a state in which the substrate is supported by the substrate support member, the substrate support member comprising:
a groove formed on a side surface of the substrate support member and constituting a flow path of the cleaning gas.
